(19) United States
(12) Patent Application Publication
(10) Pub. No.: US 2003/0033262 A1
(43) Pub. Date: Feb. 13, 2003

(54) Line connection controller

(76) Inventor: Yasutaka Aoki, Tokyo (JP)

Correspondence Address: YOUNG & THOMPSON, 745 SOUTH 23RD STREET 2ND FLOOR, ARLINGTON, VA, 22202

(21) Appl. No.: 10/207,132

(22) Filed: Jul. 30, 2002

(30) Foreign Application Priority Data
Aug. 1, 2001 (JP) 233124/2001

(51) Int. Cl. G01R 11/56

(52) U.S. Cl. 705/412

(57) ABSTRACT

A line connection controller includes a line switching device which switches connection between a subscriber line and a high-speed line, and a switching equipment which controls the line switching device in accordance with a request from a subscriber. The switching equipment includes a connection control section and message rate storage section. The connection control section instructs the line switching device to switch the line on the basis of a line connection/disconnection request from the subscriber. The message rate storage section executes charging corresponding to a high-speed line use time from connection to disconnection between the subscriber line and the high-speed line. The line switching device includes a line switching section. The line switching section switches connection between the subscriber line and the high-speed line in accordance with an instruction from the connection control section. A line connection control method and recording medium are also disclosed.

### BACKGROUND OF THE INVENTION

The present invention relates to a line connection controller which connects a subscriber line to a high-speed line as needed and provides a measured-rate high-speed line service.

High-speed line services using existing telephone lines are explosively proliferating now worldwide mainly in North America, Korea, and North Europe. As shown in FIG. 6, a conventional switching system is constituted by a switching station 1 and subscriber B 60. The switching station 1 is formed from a switching equipment (network) 61, high-speed line device 62, and splitter 63. A PC (Personal Computer) terminal of the subscriber B 60 is connected to the splitter 63 in the switching station 1 through a home terminal device, splitter, and subscriber line. The subscriber B 60 connected to the splitter 63 is connected to the switching equipment 61 and also always connected to a high-speed line through the high-speed line device 62.

However, since the conventional high-speed line service employs the form of flat rate connection, it can arouse no demand from potential customers who want to try to use the high-speed line service but require no flat rate connection or who want to use the service only when necessary.

Most high-speed line devices 62 are independent of the switching equipment 61 and are only connected to subscriber lines through the splitters 63. Hence, high-speed lines absolutely require flat rate connection. For this reason, the high-speed line devices 62 are connected to subscribers in a one-to-one correspondence. Since the load for the facilities of telecommunications carriers is added to line use charges, high-speed line services cannot be inexpensively used.

Additionally, in switching to a new high-speed line device, the service must be interrupted. Furthermore, even when the subscriber is not using the high-speed line service, the high-speed line device 62 is always operating because the high-speed line and subscriber line are always connected. Hence, the power is wasted.

Current flat-rate high-speed line service apparatuses are still expensive for subscribers who want to receive high-speed line services and communications carriers that are going to introduce high-speed line services. This impedes further popularization. In current apparatuses, since subscribers and high-speed line devices are connected in a one-to-one correspondence, installation spots, initial capital investments, power consumption, and the like make a severe burden on communications carriers. To make high-speed line services more popular in the future, it is important to reduce the initial capital investments and the burden on charges for subscribers.

High-speed line services are presently coming into the limelight because they can realize a line speed about 20-fold that of existing ISDN (Integrated Services Digital Network) services. However, flat rate connection services are not always indispensable for general subscribers except for business use.

### SUMMARY OF THE INVENTION

It is an object of the present invention to provide a line connection controller capable of providing a high-speed line service at a low line use charge.

In order to achieve the above object, according to the present invention, there is provided a line connection controller comprising a line switching device which switches connection between a subscriber line and a high-speed line, and a switching equipment which controls the line switching device in accordance with a request from a subscriber, wherein the switching equipment comprises line switching instruction means for instructing the line switching device to switch the line on the basis of a line connection/disconnection request from the subscriber, and charging means for executing charging corresponding to a high-speed line use time from connection to disconnection between the subscriber line and the high-speed line, and the line switching device comprises line switching means for switching connection between the subscriber line and the high-speed line in accordance with an instruction from the line switching instruction means.

The present invention provides a measured-rate high-speed line service for a subscriber who requires no high-speed line flat rate connection service and wants to more inexpensively enjoy a high-speed line service than a flat rate connection service, and a communications carrier who wants to inexpensively introduce a high-speed line connection service.

### BRIEF DESCRIPTION OF THE DRAWINGS

FIG. 1 is a block diagram of a switching system according to the first embodiment of the present invention;

FIG. 2 is a block diagram of a line switching device shown in FIG. 1;

FIG. 3 is a block diagram of a switching system according to the second embodiment of the present invention;

FIG. 4 is a block diagram of a switching system according to the third embodiment of the present invention;

FIG. 5 is a block diagram of a switching system according to the fourth embodiment of the present invention; and

FIG. 6 is a block diagram of a conventional switching system.

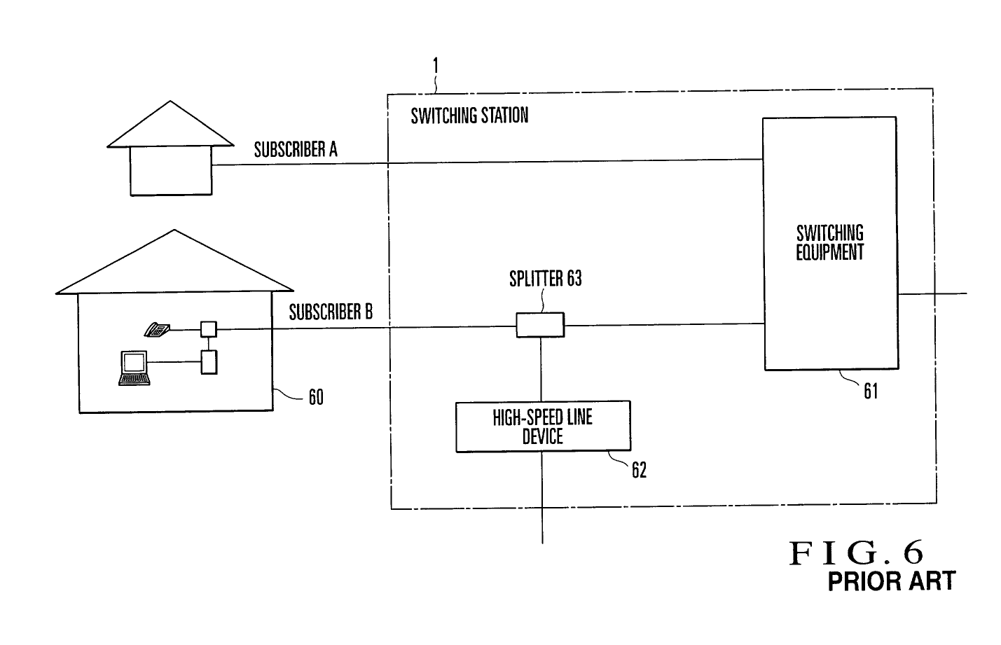

### DESCRIPTION OF THE PREFERRED EMBODIMENTS

The present invention will be described below in detail with reference to the accompanying drawings.

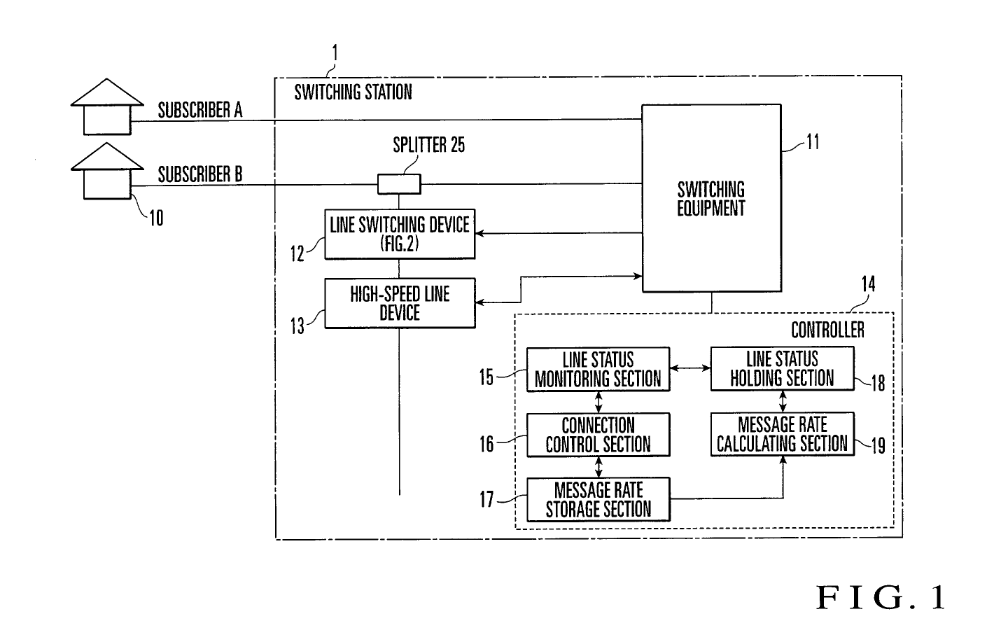

First, the principle of the present invention will be described with reference to FIG. 1. As shown in FIG. 1, a measured-rate high-speed line service is provided by inserting a line switching device 12 controllable from a switching equipment 11 between a subscriber (B) 10 and a high-speed line device 13 in a switching station 1. When the subscriber B 10 connected to the switching station 1 wants connection to a high-speed line, the subscriber B 10 issues a connection request to the switching station 1. Upon receiving the connection request, the switching equipment 11 in the switching station 1 specifies the local connection point of the subscriber B 10 and confirms the free state of lines of the high-speed line device 13 formed from a high-speed digital subscriber circuit.

If a line is free, the switching equipment 11 outputs an instruction to a line switching device 12 for switching the line at a high speed, thereby connecting the subscriber B 10 to the high-speed line device 13. Simultaneously, the switching equipment 11 instructs message rate calculation (charging operation) and maintains the connection state until the end of line connection. On the other hand, if no lines are free, the switching equipment 11 notifies the subscriber B 10 that no lines are available.

To end high-speed line connection, the subscriber B 10 sends a high-speed line connection end request to the switching equipment 11. Upon receiving from the subscriber B 10 the high-speed line connection end request that requests the end of high-speed line connection, the switching equipment 11 instructs the line switching device 12 to disconnect the line. The switching equipment 11 also stops the charging operation and stores information related to charging as a line use charge of the subscriber B 10.

In this way, only when the high-speed line service is necessary, the subscriber is connected to the high-speed line device 13 using the line switching device 12 whereby the high-speed line device 13 can be prepared in accordance with the usage of the high-speed line service. As a result, the number of local equipments can be decreased, and the line use charge of each subscriber can be reduced. For these reasons, potential subscriber demand for the high-speed line service can be awakened.

In addition, when this method is employed in which the subscriber B 10 is connected to the high-speed line device 13 through the line switching device 12 only when the high-speed line service is to be used, the number of choices of high-speed line device 13 increases. This makes it possible to cope with any extension of high-speed line services in the future. Furthermore, even during the operation of the high-speed line devices 13, they can be maintained and expanded. Additionally, categorization by service classes or charge systems also becomes possible.

An embodiment of a switching system to which the present invention is applied will be described next with reference to FIG. 1. As shown in FIG. 1, a subscriber A and subscriber B 10 are connected to a switching station 1. The switching station 1 is constituted by a switching equipment 11 to which the subscribers A and B are connected, a line switching device 12, a high-speed line device 13, and a splitter 25. The splitter 25 is connected between the switching equipment 11 and the subscriber line of the subscriber B 10. The subscriber line of the subscriber B 10 is connected to the switching equipment 11 and line switching device 12 through the splitter 25. The high-speed line device 13 is connected to the line switching device 12. The switching equipment 11 has a controller 14.

The controller 14 of the switching equipment 11 is constructed by a line status monitoring section 15, a connection control section 16 connected to the line status monitoring section 15, a message rate storage section 17 connected to the connection control section 16, a line status holding section 18 connected to the line status monitoring section 15, and a message rate calculating section 19 connected to the message rate storage section 17 and line status holding section 18.

The subscriber B 10 indicates a subscriber of a measured-rate high-speed line service. The switching equipment 11 has a line switching control program for the measured-rate high-speed line service, which is stored in advance. The line switching device 12 has a communication function of communicating with the switching equipment 11. In accordance with an instruction from the switching equipment 11, the line switching device 12 connects/disconnects the subscriber B 10 to/from a high-speed line. The high-speed line device 13 has a function of notifying the switching equipment 11 of fault information in the high-speed line device 13 and high-speed line use information.

In the controller 14 serving as a control section of the switching equipment 11, the line status monitoring section 15 always monitors a high-speed line connection request from the subscriber B 10. The connection control section 16 controls connection/disconnection to/from a high-speed line by the line switching device 12 in accordance with an instruction from the line status monitoring section 15. The line status holding section 18 grasps the use state of a high-speed line and, in response to an inquiry from the line status monitoring section 15, returns a report of the free state of the line of the high-speed line device 13. The message rate storage section 17 stores a message rate corresponding to line use time or the like after the subscriber B 10 is connected to a high-speed line service until the connection is ended (the high-speed line is disconnected). The message rate calculating section 19 calculates the line use charge on the basis of the message rate stored in the message rate storage section 17. A message rate is a unit use to calculate a line use charge. For example, one message rate corresponds to use for 3 min. One message rate corresponds to a line use charge of 10 yen.

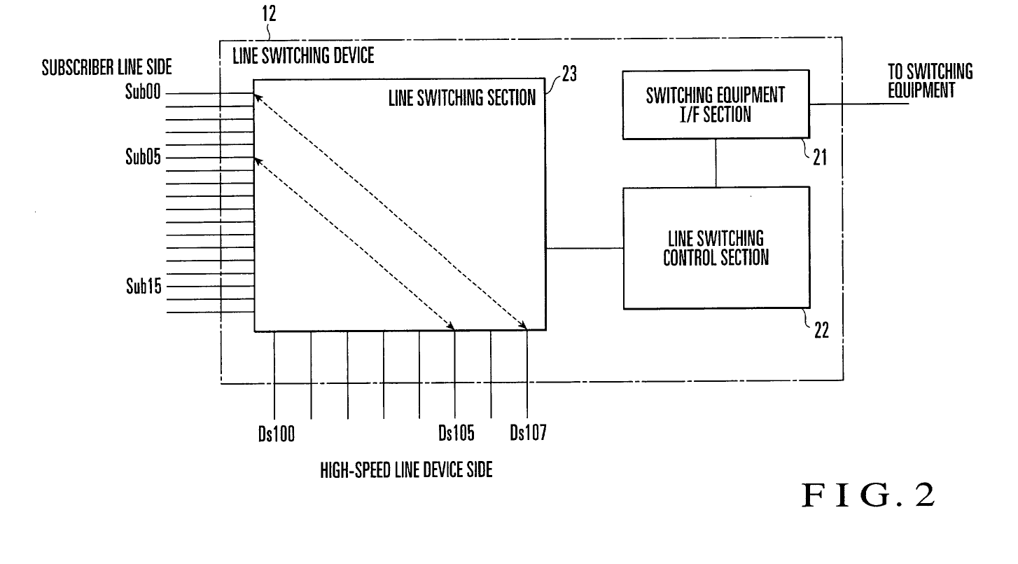

As shown in FIG. 2, the line switching device 12 is constructed by a switching equipment interface (I/F) section 21, a line switching control section 22 connected to the switching equipment I/F section 21, and a line switching section 23 connected to the line switching control section 22.

When the switching equipment 11 detects a high-speed line connection request sent from the subscriber B 10, the switching equipment 11 issues a line switching instruction to the line switching device 12 so as to switch the line connected to the subscriber B 10 to a high-speed line. The line switching instruction is received by the line switching control section 22 through the switching equipment I/F section 21. Upon receiving the line switching instruction, the line switching control section 22 controls the line switching section 23 to switch the line connected to the subscriber B 10 to a high-speed line.

FIG. 2 shows a state, by broken lines, in which Sub00 on the subscriber line side is connected to Ds107 on the high-speed line device side, and Sub05 on the subscriber line side is connected to Ds105 on the high-speed line device side. The remaining subscribers are in an idle state, i.e., the subscribers are not using high-speed lines. In this example, the subscriber line of the subscriber B 10 corresponds to, e.g., Sub05.

The operation of the above-described switching system will be described next.

First, the subscriber B 10 dials a special number designated by a communications carrier that manages the switching station 1, thereby issuing a high-speed line connection request. The high-speed line connection request is sent to the switching equipment 11. Upon receiving the high-speed line connection request from the subscriber B 10, the switching equipment 11 determines that the subscriber B 10 is requesting high-speed line connection and issues a connection request to the line status monitoring section 15 to connect the subscriber B 10 to a high-speed line. Simultaneously, the switching equipment 11 outputs target subscriber information (subscriber information such as the telephone number of the subscriber B 10) to the line status monitoring section 15.

Upon receiving the connection request and target subscriber information from the switching equipment 11, the line status monitoring section 15 inquires of the line status holding section 18 about the current line free state of the high-speed line device 13. In response to the inquiry from the line status monitoring section 15, the line status holding section 18 reports the current line use state of the high-speed line device 13. If it is determined on the basis of the report from the line status holding section 18 that no high-speed lines are available, the line status monitoring section 15 notifies the switching equipment 11 that no lines are available. Upon receiving from the line status monitoring section 15 the notification that no lines are available, the switching equipment 11 outputs a busy tone that indicates a line busy state to the subscriber B 10.

On the other hand, the report from the line status holding section 18 reveals that there is an available high-speed line, the line status monitoring section 15 notifies the switching equipment 11 that a line is available. Upon receiving from the line status monitoring section 15 the notification that a line is available, the switching equipment 11 outputs a dial tone that indicates that a line is available to the subscriber B 10.

Next, the line status monitoring section 15 notifies the connection control section 16 of the subscriber information of the subscriber B 10 who is requesting line connection and instructs the connection control section 16 to connect the line. The connection control section 16 issues a high-speed line connection instruction to the line switching device 12 through the switching equipment 11. The connection control section 16 also instructs the message rate storage section 17 to start measuring the message rate and store the measured message rate. With this operation, a message rate corresponding to a connection time from the timing when the subscriber B 10 is connected to the high-speed line is measured and stored by the message rate storage section 17.

When the subscriber B 10 is going to end use of the high-speed line, the subscriber B 10 dials another special number designated by the communications carrier or turns off the power of the home terminal device. With this operation, a line disconnection request can be issued to the switching equipment 11 side. The line status monitoring section 15 always monitors the subscriber B 10 during high-speed line connection. Upon receiving the line disconnection request from the subscriber B 10, the line status monitoring section 15 issues a disconnection request to the connection control section 16. The line disconnection request is received not only when the subscriber B 10 dials the special number or turns off the power of the home terminal device but also when a line fault is detected, or a disconnection instruction by an operator is received.

Upon receiving the disconnection request from the line status monitoring section 15, the connection control section 16 instructs the line switching device 12 to disconnect the high-speed line from the subscriber B 10 and also instructs the message rate storage section 17 to stop measuring and storing the message rate. Upon receiving the message rate measurement and storage stop instruction, the message rate storage section 17 stops measuring and storing the message rate and notifies the message rate calculating section 19 of the stored message rate. The message rate calculating section 19 calculates and stores the line use charge of the high-speed line of the subscriber B 10 on the basis of the message rate received from the message rate storage section 17. After that, the line status monitoring section 15 notifies the line status holding section 18 of the disconnected high-speed line.

According to this embodiment, in providing a measured-rate high-speed line service, the communications carrier of high-speed lines need not install high-speed line devices 13 equal in number to the contract lines. Since the cost of the line switching device 12 is much lower than that of the high-speed line device 13, the cost of the entire system can be reduced. A subscriber can also be connected to a high-speed line, as needed, for a low basic charge and use charge by introducing a measured-rate system and avoid unwanted expenses. In addition, a subscriber who hesitates a new contract may try to use the service.

In the conventional flat-rate high-speed line service, when a line device with a higher speed is to be introduced and connected to the line switching device 12, the service for subscribers must be temporarily stopped. According to this embodiment, other services need not be stopped. In addition, a service may be provided in which a single subscriber may make contracts of two kinds of high-speed lines with different communication rates or line use charges by different contract forms such that the two kinds of high-speed lines can selectively be used in accordance with the purpose.

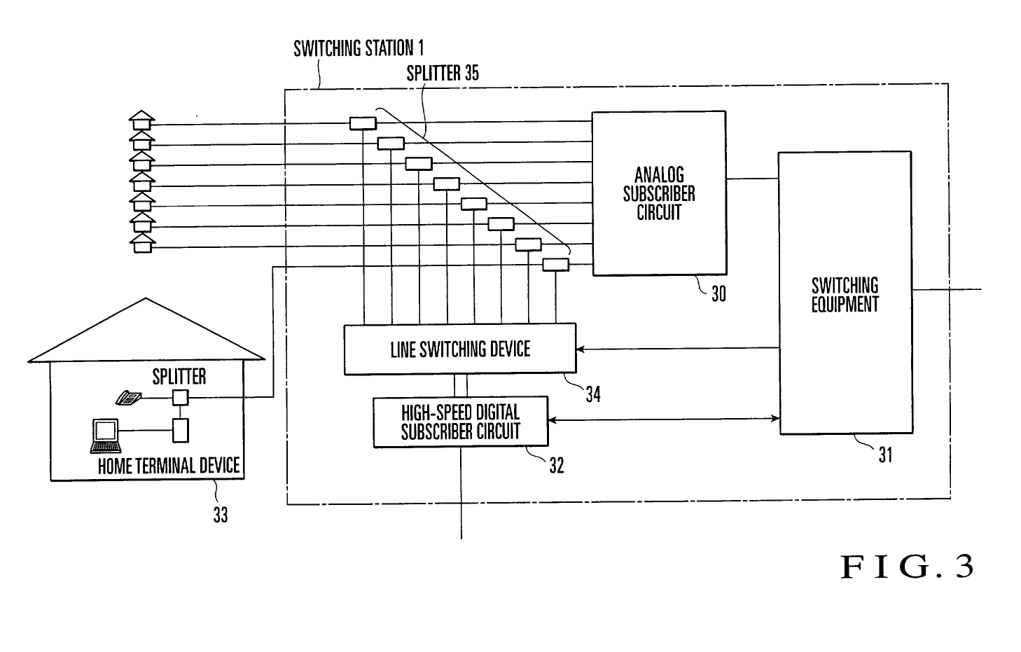

The second embodiment of the present invention will be described next with reference to FIG. 3. As shown in FIG. 3, a switching station 1 according to this embodiment is constituted by an analog subscriber circuit 30 to which a plurality of analog subscribers are connected, a switching equipment 31 connected to the analog subscriber circuit 30, a high-speed digital subscriber circuit 32 serving as a high-speed line device, a home terminal device 33 in the subscriber home, a line switching device 34, and a plurality of splitters 35 connected to the high-speed digital subscriber circuit 32 through the line switching device 34.

The plurality of splitters 35 are connected between the subscriber lines of the plurality of analog subscribers and the analog subscriber circuit 30. The line switching device 34 is connected between the splitters 35 and the high-speed line device 32. The line switching device 34 connects a subscriber line to the high-speed line device 32 in accordance with an instruction from the switching equipment 31. With this operation, the subscriber can use a high-speed line. Upon receiving a disconnection request from the subscriber, the switching equipment 31 instructs the line switching device 34 to disconnect the high-speed line. The line switching device 34 disconnects the subscriber line from the high-speed line device 32.

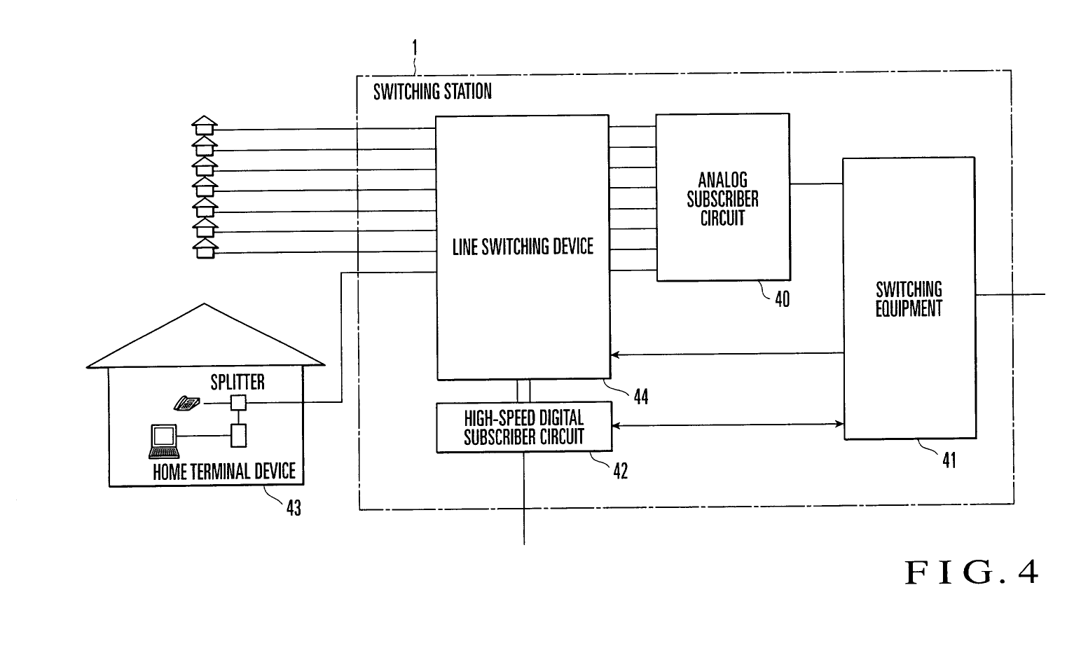

The third embodiment of the present invention will be described next with reference to FIG. 4. As shown in FIG. 4, a switching station 1 according to this embodiment is constituted by an analog subscriber circuit 40 to which a plurality of analog subscribers are connected, a switching equipment 41 connected to the analog subscriber circuit 40, a high-speed digital subscriber circuit 42, a home terminal device 43 in a subscriber home, and a line switching device 44. The line switching device 44 is connected between the analog subscriber circuit 40 and the subscriber lines of the plurality of analog subscribers including the home terminal device 43. The plurality of analog subscribers are selectively connected to the analog subscriber circuit 40 and high-speed digital subscriber circuit by the line switching device 44.

The line switching device 44 can load a splitter function that can be disabled for a line card in a high-speed line, which requires no splitter function. When a subscriber installs a higher-speed home terminal device in his home, he can selectively use both the subscriber line and the high-speed line in accordance with the application purpose without requiring new construction on the switching station 1 side.

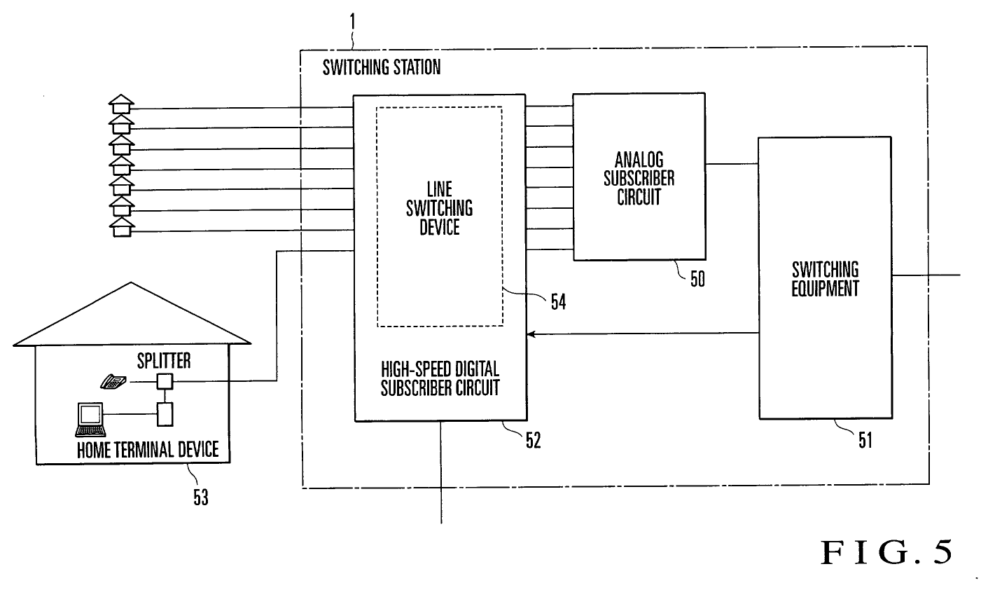

The fourth embodiment of the present invention will be described next with reference to FIG. 5. As shown in FIG. 5, a switching station 1 according to this embodiment is constituted by an analog subscriber circuit 50 to which a plurality of analog subscribers are connected, a switching equipment 51 connected to the analog subscriber circuit 50, a high-speed digital subscriber circuit 52, a line switching device 54 incorporated in the high-speed digital subscriber circuit 52, and a home terminal device 53 in a subscriber home. In this example, the line switching device 54 is integrated with the high-speed digital subscriber circuit 52.

In this embodiment, the mounting efficiency can be improved, and simultaneously, construction becomes easy. For a line card in a high-speed line, which requires no splitter function, the internal splitter function can be disabled. According to this embodiment, since the high-speed digital subscriber circuit 52 and line switching device 54 are integrated to make the apparatus compact, it can easily be introduced to a medium- or small-scale switching station 1.

A method of causing the subscriber to operate a PC (Personal Computer) terminal connected to the home terminal device 33 and transmit a high-speed line connection request and disconnection request to the switching equipment 31 will be described next with reference to FIG. 3.

As the first method, the home terminal device 33 incorporates a splitter and PB (Push Button) signal transmitting/receiving device are incorporated. In this arrangement, the PB signal transmitting/receiving device is controlled by dedicated software of the PC terminal connected to the home terminal device 33, thereby transmitting/receiving codes for which an agreement has been concluded in advance with the switching equipment 31 side and exchanging a high-speed line connection request and disconnection request.

As the second method, the home terminal device 33 incorporates a splitter and FSK (Frequency Shift Keying) transmitting/receiving device. In this arrangement, the FSK transmitting/receiving device is controlled by dedicated software of the PC terminal connected to the home terminal device 33, thereby transmitting/receiving codes for which an agreement has been concluded in advance with the switching equipment 31 side and exchanging a high-speed line connection request and disconnection request.

As the third method, the home terminal device 33 incorporates a splitter and modem transmitting/receiving device. In this arrangement, the modem transmitting/receiving device is controlled by dedicated software of the PC terminal connected to the home terminal device 33, thereby transmitting/receiving codes for which an agreement has been concluded in advance with the switching equipment 31 side and exchanging a high-speed line connection request and disconnection request.

As described above, in the above embodiments, the following effects can be obtained. First, high-speed line devices, e.g., flat-rate connection lines such as ADSL (Asymmetric Digital Subscriber Line) conventionally basically employ one-to-one connection. However, according to the above embodiments, one high-speed line device can be connected to a number of subscribers by N-to-one connection. Hence, the facility cost can be decreased. In addition, since each subscriber selects a desired line from a plurality of high-speed lines in accordance with the purpose, the line connection charge can be saved.

As has been described above, according to the present invention, a subscriber line can be connected to a high-speed line, as needed, and a high-speed line service can be provided for a low line use charge.

What is claimed is:

1. A line connection controller comprising:
a line switching device which switches connection between a subscriber line and a high-speed line; and
a switching equipment which controls said line switching device in accordance with a request from a subscriber,
wherein
said switching equipment comprises
line switching instruction means for instructing said line switching device to switch the line on the basis of a line connection/disconnection request from the subscriber, and
charging means for executing charging corresponding to a high-speed line use time from connection to disconnection between the subscriber line and the high-speed line, and
said line switching device comprises
line switching means for switching connection between the subscriber line and the high-speed line in accordance with an instruction from said line switching instruction means.

2. A controller according to claim 1, wherein
said line switching instruction means instructs said line switching device to connect the subscriber line to the high-speed line on the basis of the line connection request from the subscriber and instructs said line switching device to disconnect the subscriber line from the high-speed line on the basis of the line disconnection request from the subscriber, and
said line switching means connects the subscriber line to the high-speed line in accordance with a connection request from said line switching instruction means and disconnects the subscriber line from the high-speed line in accordance with a disconnection request from said line switching instruction means.

3. A controller according to claim 1, wherein said switching equipment comprises line state holding means for grasping a use state of the high-speed line and storing the use state and also reports a free state of the high-speed line to said line switching instruction means.

4. A controller according to claim 3, wherein
said line switching instruction means inquires of said line state holding means about whether a high-speed line is free upon receiving the line connection request from the subscriber, and
when it is reported by said line state holding means that a high-speed line is free, said line switching instruction means sends a dial tone to the subscriber and simultaneously instructs said line switching device to switch the line.

5. A controller according to claim 3, wherein
said line switching instruction means inquires of said line state holding means about whether a high-speed line is free upon receiving the line connection request from the subscriber, and
when it is reported by said line state holding means that no high-speed line is free, said line switching instruction means sends a busy tone to the subscriber.

6. A controller according to claim 1, wherein
the subscriber sends the line connection request to said switching equipment by dialing a special number, and
said line switching means instructs said line switching device to connect the line on the basis of the line connection request from the subscriber.

7. A controller according to claim 1, wherein
the subscriber sends the line disconnection request to said switching equipment by dialing a special number, and
said line switching means instructs said line switching device to disconnect the line on the basis of the line disconnection request from the subscriber.

8. A line connection control method for a switching system comprising a line switching device which switches connection between a subscriber line and a high-speed line and a switching equipment which controls the line switching device in accordance with a request from a subscriber, comprising the steps of:
causing the switching equipment to monitor a line connection request and line disconnection request from the subscriber;
causing the switching equipment to instruct the line switching device to switch the line on the basis of the line connection/disconnection request from the subscriber;
causing the switching equipment to execute charging corresponding to a high-speed line use time from connection to disconnection between the subscriber line and the high-speed line; and
causing the line switching device to switch connection between the subscriber line and the high-speed line in accordance with a line switching instruction from the switching equipment.

9. A method according to claim 8, wherein
the line switching instruction step comprises the step of causing the switching equipment to instruct the line switching device to connect the subscriber line to the high-speed line on the basis of the line connection request from the subscriber, and
the connection switching step comprises the step of connecting the subscriber line to the high-speed line in accordance with the connection instruction from the switching equipment.

10. A method according to claim 8, wherein
the line switching instruction step comprises the step of causing the switching equipment to instruct the line switching device to disconnect the subscriber line from the high-speed line on the basis of the line disconnection request from the subscriber, and
the connection switching step comprises the step of disconnecting the subscriber line from the high-speed line in accordance with the disconnection instruction from the switching equipment.

11. A computer-readable recording medium which records in advance a line connection control program for a switching system comprising a line switching device which switches connection between a subscriber line and a high-speed line and a switching equipment which controls the line switching device in accordance with a request from a subscriber, the recording medium recording a line connection control program which causes a computer to execute the procedures of:
monitoring a line connection request and line disconnection request from the subscriber;
causing the switching equipment to instruct the line switching device to switch the line on the basis of the line connection/disconnection request from the subscriber;
executing charging corresponding to a high-speed line use time from connection to disconnection between the subscriber line and the high-speed line; and
switching connection between the subscriber line and the high-speed line in accordance with a line switching instruction.

12. A medium according to claim 11, wherein
the line switching instruction procedure comprises the procedure of instructing connection between the subscriber line and the high-speed line on the basis of the line connection request from the subscriber, and
the connection switching procedure comprises the procedure of connecting the subscriber line to the high-speed line in accordance with the connection instruction.

13. A medium according to claim 11, wherein
the line switching instruction procedure comprises the procedure of instructing disconnection between the subscriber line and the high-speed line on the basis of the line disconnection request from the subscriber, and
the connection switching procedure comprises the procedure of disconnecting the subscriber line from the high-speed line in accordance with the disconnection instruction.
